(19) United States
(12) Patent Application Publication
(10) Pub. No.: US 2009/0072815 A1
(43) Pub. Date: Mar. 19, 2009

(54) CALIBRATION OF A MAGNETIC SENSOR DEVICE

(75) Inventors: Josephus Arnoldus Henricus Maria Kahlman, Tilburg (NL); Menno Willem Jose Prins, Rosmalen (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/298,066

(22) PCT Filed: Apr. 16, 2007
(86) PCT No.: PCT/IB2007/051351

§ 371 Date: Oct. 22, 2008

(30) Foreign Application Priority Data
Apr. 26, 2006 (EP) 06113113.2

(51) Int. Cl. G01N 27/72; G01R 35/00; G01R 33/12

(52) U.S. Cl. 324/202; 324/232

(57) ABSTRACT

The invention relates to the calibration of the magnetic sensor device comprising magnetic excitation wires (11, 13) and a magnetic sensor element, for example a GMR sensor (12), for measuring reaction fields (B₂) generated by magnetic particles (2) in reaction to an excitation field (B₁) generated by the excitation wires. The magnetic sensor element (12) can be calibrated by saturating the magnetic particles (2) with a magnetic calibration field (B₃). Thus the direct (crosstalk) action of the excitation field (B₁) on the magnetic sensor element (12) can be determined without disturbing contributions of the magnetic particles (2).

The invention relates to a magnetic sensor device comprising at least one magnetic excitation field generator and at least one magnetic sensor element. Moreover, the invention relates to the use of such a magnetic sensor device and a method for detecting magnetic particles with such a magnetic sensor device.

From the WO 2005/010543 A1 and WO 2005/010542 A2 a magnetic sensor device is known which may for example be used in a microfluidic biosensor for the detection of (e.g. biological) molecules labeled with magnetic beads. The microsensor device is provided with an array of sensor units comprising wires for the generation of a magnetic field and Giant Magneto Resistance devices (GMRs) for the detection of stray fields generated by magnetized beads. The resistance of the GMRs is then indicative of the number of the beads near the sensor unit.

A problem with magnetic biosensors of the aforementioned kind is that the sensitivity of the magneto-resistive elements and therefore the effective gain of the whole measurements is very sensitive to uncontrollable parameters like magnetic instabilities in the sensors, external magnetic fields, aging, temperature and the like.

Based on this situation it was an object of the present invention to provide means for making the measurements of magnetic sensor devices more robust against variations in sensor gain.

This objective is achieved by a magnetic sensor device according to claim 1, by a method according to claim 2, and by a use according to claim 16. Preferred embodiments are disclosed in the dependent claims.

A magnetic sensor device according to the present invention serves for detecting magnetic particles in an investigation region, for example in an adjacent sample chamber. In this context, the term “magnetic particle” shall refer to any kind of material (molecules, complexes and especially nanoparticles) that can be magnetized when being exposed to a magnetic field. The magnetic particles may for instance serve as labels for target molecules one is actually interested in. The magnetic sensor device comprises the following components:

a) At least one magnetic excitation field generator for generating a magnetic excitation field in the investigation region.

b) At least one magnetic calibration field generator for generating a magnetic calibration field in the investigation region, wherein said calibration field has at least temporarily a sufficient magnitude to change the magnetization characteristics of magnetic particles that are present in the investigation region.

c) At least one magnetic sensor element for measuring (inter alia) magnetic reaction fields generated by magnetic particles in the investigation region in reaction to the magnetic excitation field and/or the magnetic calibration field.

c) An evaluation unit for calibrating the magnetic sensor element based on measurements of said element, wherein magnetic particles are present and wherein a magnetic excitation field and/or a magnetic calibration field prevails in the investigation region during said measurements. The evaluation unit may for example be realized by an on-chip circuitry or by an external microcomputer.

Moreover, the invention relates to a method for detecting magnetic particles in an investigation region which comprises the following steps:

a) Generating a magnetic excitation field in the investigation region with at least one magnetic excitation field generator.

b) Generating a magnetic calibration field in the investigation region with at least one magnetic calibration field generator, wherein said field has at least temporarily a sufficient magnitude to change the magnetization characteristics of magnetic particles in the investigation region.

c) Measuring magnetic reaction fields with at least one magnetic sensor element, wherein said fields are generated by magnetic particles in the investigation region in reaction to the magnetic excitation field and/or the magnetic calibration field.

d) Calibrating the magnetic sensor element based on measurements with a magnetic excitation field and/or a magnetic calibration field and with magnetic particles in the investigation region.

The magnetic sensor device and the method described above make use of a magnetic calibration field that can change the magnetization characteristics of the magnetic particles which shall be detected. This allows to change the reactions of said particles to an excitation field accordingly. On the other hand, the magnetic crosstalk between the excitation field generator and the magnetic sensor element is not affected by the calibration field. A comparison between measurements generated with the same excitation field but different calibration fields therefore allows to infer the contribution coming from magnetic crosstalk. As this contribution is independent of the (unknown) amount of particles present in the investigation region, it can be used to determine the sensor gain.

The evaluation unit may optionally be adapted to determine the amount of magnetic particles in the investigation region based on measurements which were generated during times in which the magnetic calibration field at least approximately vanishes in the investigation region. The amount of magnetic particles present in the investigation region (or, if particles of the same kind are concerned, their number) is the parameter one actually wants to know. If the calibration field is zero, it can be determined as usual with magnetic excitation fields only. The corresponding measurements will however achieve a higher accuracy because they can be calibrated based on previous and/or subsequent measurements with a magnetic calibration field.

In another embodiment, the magnetic calibration field vanishes repeatedly. The aforementioned detection of the magnetic particles without disturbances by calibration fields can then be repeated accordingly, wherein the intermediate times during which the calibration field is nonzero can be used to update the calibration of the magnetic sensor element.

According to a preferred embodiment of the invention, the magnetic calibration field is chosen so large that it saturates the magnetic particles at least temporarily. During the times of saturation, the magnetic particles cannot react to variations of the magnetic excitation field, which allows to identify the direct effect of this field on the magnetic sensor element (i.e. the magnetic crosstalk).

The magnetic excitation field has preferably a nonzero excitation frequency, wherein the term “frequency” is understood here and in the following as the repetition frequency of a periodic pattern. The Fourier spectrum of the excitation field may therefore comprise the excitation frequency as a basic frequency together with other frequencies, e.g. higher harmonics of the excitation frequency. Using an alternating excitation field allows a facilitated detection of contributions that are due to this field in the spectrum of the sensor signal.

Moreover, the magnetic calibration field may have a nonzero calibration frequency. The calibration field may for example be a square-wave field that periodically switches between two values, e.g. zero and a nonzero value, or a field that switches between zero and an alternating course. The calibration frequency and the aforementioned excitation frequency may be the same, or they may be different.

In another embodiment of the invention, the magnetic sensor element is driven with a nonzero sensing frequency. Such a frequency allows to detect influences of the driving operation in the sensor signal and to position signal components one is interested in optimally with respect to noise in the signal spectrum.

The magnetic excitation field generator and the magnetic calibration field generator may in principle be the same component, for example a wire on a sensor chip; excitation and calibration fields might then be generated by a superposition of corresponding currents. A problem of this design is however that in many cases the calibration fields required for a change of the magnetization characteristics of the magnetic particles have to be so large that they also significantly change the characteristics of the magnetic sensor element. This is undesirable, as a calibration should determine the sensor characteristics as they are during normal measurements, i.e. without a calibration field. According to a preferred embodiment of the invention, the magnetic calibration field is therefore adjusted such that it is minimized (preferably to a value of essentially zero) in the magnetic sensor element (or, more precisely, in the sensitive region thereof) with respect to the sensitive direction of the magnetic sensor element. The “sensitive direction” of the magnetic sensor element means that the sensor element is most (or only) sensitive with respect to components of a magnetic field vector that are parallel to said spatial direction. Usually, the magnetic sensor element has only one sensitive direction and is substantially insensitive to components of a magnetic field perpendicular to this direction. The magnetic calibration field is then preferably oriented in said insensitive direction, which typically requires the calibration field generator to be different from the excitation field generator.

The evaluation unit may optionally be adapted to determine that component of the measurement signals that is directly due to the magnetic calibration field inside the magnetic sensor element (or, more precisely, in its sensitive region). Such a determination can then be used to adjust the magnetic calibration field—particularly its orientation—in such a way that this component is minimized or even completely removed. Thus the optimal conditions of the aforementioned embodiment can be reached and preserved in a feedback procedure.

The magnetic (excitation/calibration) field generators can be realized in many different ways. Preferably, they comprise at least one conductor wire, which may be disposed on or in a substrate of the magnetic sensor device.

In a particularly embodiment of the invention, the magnetic excitation field generator and the magnetic calibration field generator are at least partially realized in the same hardware, e.g. by the same integrated wire on a chip.

The magnetic calibration field generator may comprise at least one coil for an external generation of the calibration field.

The magnetic sensor element may particularly be realized by a Hall sensor or by a magneto-resistive element, for example a GMR (Giant Magnetic Resistance), a TMR (Tunnel Magneto Resistance), or an AMR (Anisotropic Magneto Resistance). Moreover, the magnetic excitation field generator and the magnetic sensor element may be realized as an integrated circuit, for example using CMOS technology together with additional steps for realizing the magneto-resistive components on top of a CMOS circuitry. Said integrated circuit may optionally also comprise the magnetic calibration field generator and/or the evaluation unit.

The invention further relates to the use of the magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

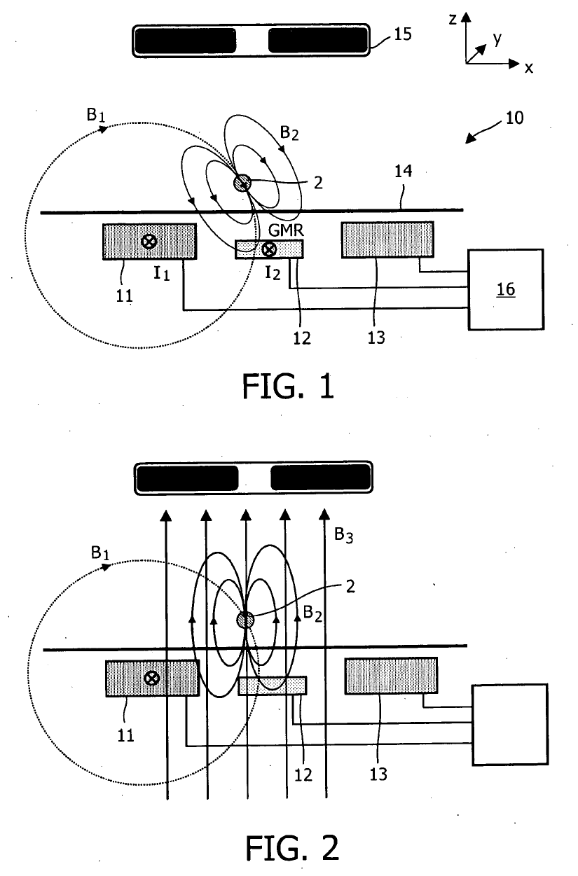

FIG. 1 schematically shows a magnetic sensor device according to the present invention during a measurement;

FIG. 2 shows the magnetic sensor device of FIG. 1 during a calibration;

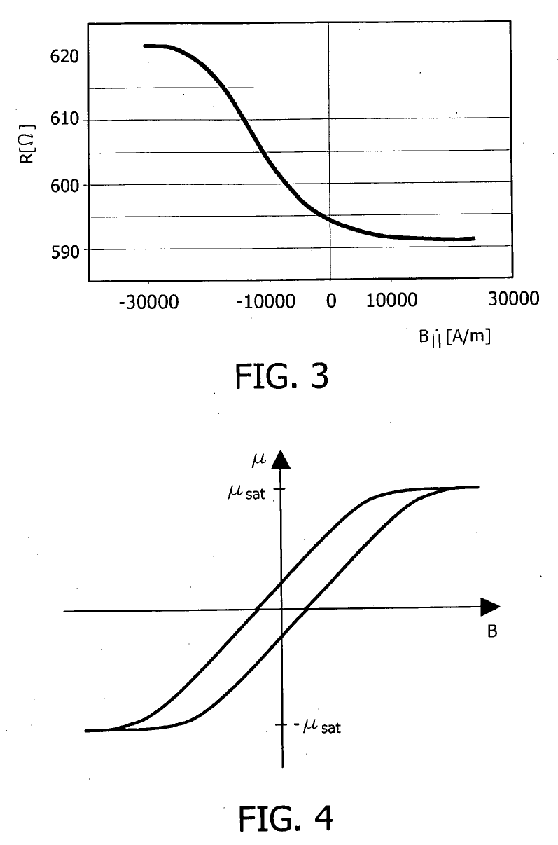

FIG. 3 illustrates the resistance of a GMR sensor in dependence on the applied magnetic field;

FIG. 4 illustrates the magnetization behavior of magnetic particles.

Like reference numbers in the Figures refer to identical or similar components.

FIG. 1 illustrates a magnetic sensor device 10 according to the present invention in the particular application as a biosensor for the detection of magnetically interactive particles, e.g. superparamagnetic beads 2 in a sample chamber. Magneto-resistive biochips or biosensors have promising properties for bio-molecular diagnostics, in terms of sensitivity, specificity, integration, ease of use, and costs. Examples of such biochips are described in the WO 2003/054566, WO 2003/054523, WO 2005/010542 A2, WO 2005/010543 A1, and WO 2005/038911 A1, which are incorporated into the present application by reference.

A biosensor typically consists of an array of (e.g. 100) sensor devices 10 of the kind shown in FIG. 1 and may thus simultaneously measure the concentration of a large number of different target molecules (e.g. protein, DNA, amino acids, drugs of abuse) in a solution (e.g. blood or saliva). In one possible example of a binding scheme, the so-called “sandwich assay”, this is achieved by providing a binding surface 14 with first antibodies to which the target molecules may bind. Superparamagnetic beads 2 carrying second antibodies may then attach to the bound target molecules (for clarity the antibodies and target molecules are not shown of the Figure).

A current I₁ flowing in at least one of the excitation wires 11 and 13 of the sensor device 10 generates a magnetic excitation field B₁, which then magnetizes the superparamagnetic beads 2. The stray field B₂ from the superparamagnetic beads 2 introduces an in-plane magnetization component in the sensitive direction (here the x-direction) of the Giant Magneto Resistance (GMR) 12 of the sensor device 10, which results in a measurable resistance change. Said resistance change is determined with the help of a sensor current I₂ and the resulting voltage drop u.

FIG. 3 shows in this context the GMR resistance R as a function of the magnetic field component B_{∥} parallel to the sensitive direction of the GMR element (i.e. the sensitive layer of the GMR stack). The slope of the curve corresponds to the sensitivity S_{GMR} of the magnetic sensor element 12 and depends on B₁. Unfortunately the sensitivity S_{GMR} and therefore the effective gain (i.e. the derivative du/dB_{∥}) of the measurement is sensitive to non-controllable parameters, for example:
stochastic sensitivity variations due to magnetic instabilities in the sensor;
externally applied magnetic fields;
production tolerances;
aging effects;
temperature;
memory effects from e.g. magnetic actuation fields;
gain variations in the current sources and the detection electronics.

Furthermore internal compensation techniques for parasitic magnetic and capacitive crosstalk will fail when the GMR sensitivity varies.

The approach proposed here for solving the aforementioned problems tries to determine the effective gain of the biosensor system by applying magnetic calibration fields to the sensor in such a way that the calibration field is hardly affected by the presence of beads near the sensor. At the same time, the applied fields shall still enable a bead detection process.

For a particular realization of the aforementioned concept, the magnetic sensor device 10 of FIG. 1 comprises at least one external coil 15 for generating a magnetic calibration field B₃ (cf. FIG. 2) and an evaluation unit 16 to which the excitation wires 11, 13 and the GMR sensor 12 are coupled. The evaluation unit may be realized by analog or digital circuits integrated into the substrate of the sensor device 10 and/or by an external digital processing unit (e.g. a workstation) with appropriate software. Additionally or alternatively to the external coil 15, means for generating a calibration field might also be located on the sensor chip.

The basic idea is now to magnetically ‘freeze’ or saturate the magnetic beads 2, so that the gain of the detection system including the GMR sensor may be calibrated during the actual bio-chemical reaction.

FIG. 4 schematically shows the magnetization μ of the magnetic beads 2 in dependence on the magnetic field B they are exposed to (the shown hysteresis may be present or not). It can be seen that the magnetization a saturates if the field B exceeds certain limits. Typical values of such saturation fields of the beads are 10-100 mT.

In comparison to this, the saturation fields of magneto-resistive sensors (cf. FIG. 3) can be about 10 mT (8000 A/m), but only when the fields are applied in the sensitive x-direction of the sensor. To avoid a sensor saturation, a magnetic “calibration” field B₃ that is essentially orthogonal to the sensitive x-direction of the GMR sensor 12 (i.e. that is directed in the z-direction in FIG. 2) is therefore applied to saturate the magnetic beads 2. This eliminates the magnetic response of the magnetic beads 2, so that the total gain of the detection system may be calibrated during the progress of the bio-chemical reaction by measuring the magnetic crosstalk from the field generating wires 11, 13 towards the GMR sensor 12. During the bio-chemical measurement the biosensor measures the beads and calibrates the detection, including the GMR sensor, in an alternating way. Note that in this way also fluctuations of the excitation currents I₁ and the sensor currents I₂ are compensated.

In the following, a more detailed analysis of the calibration and measurement procedure will be given. It starts with the measured GMR voltage signal u:

u=R·I₂+α·I₁=[R₀+g·B₁]·I₂+α·I₁ (1)

with

u=measured voltage across the GMR when a sensor current I₂ is conducted through it

R=dynamic resistance of GMR

R₀=static resistance of GMR

I₁=excitation current of frequency f₁

I₂=sensor current of frequency f₂

g=g(t)=(unknown, variable) gain (assuming an operation in the linear region of FIG. 3)

B_{∥}=components in sensitive x-direction of GMR of all acting magnetic fields

α=constant related to the parasitic capacitive and inductive crosstalk.

The magnetic field component B_{∥} is composed of B₁, B₂ and B₃ according to:

B_{∥}=a·I₁+b·N·μ(I₁,B₃)+c·B₃ (2)

with

a=constant related to the magnetic crosstalk

b=constant related to the bead responses

c=constant related the calibration field

N=N(t)=(unknown, variable) number of beads

μ(I₁,B₃)=magnetization of beads

B₃=magnetic calibration field of frequency f₃.

Combining equations (1) and (2) yields:

u=[R₀+g·(a·I₁+b·N·μ(I₁,B₃)+c·B₃)]·I₂+α·I₁ (3)

As the quantities I₁, I₂, and B₃ have characteristic frequencies f₁, f₂, and f₃, respectively, individual summands can be separated from the measured voltage u by demodulation with an appropriate demodulation frequency. For the following further analysis it is assumed that f₁>0 and f₂ >0.

During a measurement, B₃ vanishes, and μ becomes proportional to I₁: μ(I₁,B₃=0)=d·I₁. Demodulation of equation (3) with a proper frequency (f₁±f₂) yields then the quantity

g·(a+b·N·d)·I_{1,0}·I_{2,0} (4)

with

d=constant

I_{1,0}=(constant, known) amplitude of the excitation current I₁

I_{2,0}=(constant, known) amplitude of the sensor current I₂.

In equation (4), an unknown magnetic crosstalk component g·a and an unknown temporal variation of the gain g=g(t) prevent the accurate determination of the number N of beads one is interested in. These problems can however be addressed with additional calibration measurements during which B₃≠0. For these calibrations, three cases can then be distinguished with respect to f₃:

1. Case: The magnetic calibration field B₃ is a DC field with amplitude B_{3,0} and frequency f₃=0:

During a calibration, B_{3,0} is so large that μ(I₁,B_{3,0})=μₛₐₜ independent of I₁. Demodulation of equation (3) with a proper frequency (f₁±f₂) yields then the quantity

g·a·I_{1,0}·I_{2,0} (5)

which is the magnetic crosstalk component. Subtracting this magnetic crosstalk component from measurements according to expression (4) yields

g(t)·b·N(t)·d·I_{1,0}·I_{2,0} (6)

which comprises the number N of beads one is interested in together with the time-varying gain g(t) and some constants. Any temporal variations of the gain g(t) can however be detected by observing the calibration results (5) over time, and thus these variations can be distinguished from variations in N(t) (which one wants to know) in the measurement result (6).

2. Case: The magnetic calibration field B₃ is a square-wave field oscillating between two values ±B_{3,0} with frequency f₃≠f₁:

In this case the magnetization μ varies with the same frequency f₃ according to μ(I₁,±B_{3,0})=±μₛₐₜ independent of I₁. As f₃≠f₁, equation (3) can be demodulated as in Case 1 with a proper frequency (f₁±f₂) to yield the term (5). Further analysis is then the same as in Case 1.

3. Case: The magnetic calibration field B₃ is a square-wave field oscillating between two values ±B_{3,0} with frequency f₃=f₁:

In this case the magnetization μ varies between ±μₛₐₜ with the same frequency f₁ as the magnetic crosstalk component a·I₁ in equation (3). Demodulation of equation (3) with a proper frequency (f₁±f₂) yields then the quantity

g·(a·I_{1,0}+b·N·μₛₐₜ)·I_{2,0} (7)

Combining expressions (4) and (7) yields

g(t)·b·N(t)·(μₛₐₜ−d)·I_{1,0}·I_{2,0} (8)

which is similar to expression (6) besides a replacement of constant d by constant (μₛₐₜ−d). The further analysis of this measurement result can however proceed as in Case 1.

In the analysis above it was assumed that the calibration field B₃ has always a magnitude ±B_{3,0} that saturates the beads 2. The calibration field B₃ may however also oscillate between such a magnitude B_{3,0} and the value zero. In this case, the beads are swept between a saturated and sensitive regime at frequency f₃, which can be viewed as a kind of field-gating method. As in the cases analyzed above, this generates higher harmonic signals (second and third) and respective mixing signals (mixing between harmonics of f₁, f₂, and f₃). Signals components will then be characteristic for the sensor response and for the presence of the magnetic particles, respectively.

The magneto-resistive signal at frequency f₃ may optionally be used to tune the direction of the applied magnetic calibration field B₃, e.g. to orient it into an out-of-plane direction (z-direction in FIG. 2).

In a modification of the described approaches, the beads are not completely saturated, but shifted across their non-linear magnetic characteristic. This measure effectively changes the magnetic response of the beads, and thus the overall detection gain. When for example said gain decreases a factor of two by applying the magnetic field, the detection gain without the field may be calibrated by observing the gain difference. This method requires a well-calibrated bead magnetization change.

In still another embodiment the magnetic beads do have a hysteresis characteristic introduced by e.g. magnetic remanence, coercive field, or magnetic anisotropy. By applying a preferably vertical (z-direction in FIGS. 1, 2) magnetic calibration field, the operating point of the beads is shifted between a sensitive (inner loop) and a non-sensitive regime (saturated regime). The required magnetic field to implement this embodiment is typically smaller than the required field for the aforementioned embodiment. This is because a small calibration field may shift the bead from the linear to the saturated region. As an example a constant magnetic field (permanent magnet) may serve as a “bias” for magnetic beads having a hysteresis, so that the required field change (induced by external coils) is small (less power consumption, small coils etc).

The sensitivity S_{GMR} of the GMR sensor is preferably measured in the same frequency range in which the beads excitation is performed. This is because of reasons of signal-to-noise ratio SNR (to reduce the influence of 1/f noise, small current, small voltage) and to be consistent to the bead measurement.

Although the invention was explained in the Figures with respect to a biosensor based on an integrated excitation of superparamagnetic nano-particles, it can also be applied in other magneto-resistive sensors likes AMR and TMR and in combination with an external excitation method. Moreover, the invention is also applicable to other configurations of the magneto-resistive element (e.g. Wheatstone bridges or half-Wheatstone bridges) or to various amplifier and sensor current means.

In another variant of the invention, the calibration field may be internally generated, e.g. by a low-duty cycle, high amplitude current (to limit dissipation) in integrated wires. Said wires might be the excitation wires, which are operated bi-functionally in this case, or separate wires. Preferably the magnetic crosstalk from the internal wires generating the calibration field to the sensor is minimized in this embodiment by e.g. a vertical (z-direction) alignment of the centers of said wires and the sensor.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (10) for detecting magnetic particles (2) in an investigation region, comprising:
a) at least one magnetic excitation field generator (11, 13) for generating a magnetic excitation field (B1) in the investigation region;
b) at least one magnetic calibration field generator (15) for generating a magnetic calibration field (B3) in the investigation region which has at least temporarily a sufficient magnitude to change the magnetization characteristics of magnetic particles (2) in the investigation region;
c) at least one magnetic sensor element (12) for measuring magnetic reaction fields (B2) generated by magnetic particles (2) in the investigation region in reaction to the magnetic excitation field (B1) and/or the magnetic calibration field (B3);
d) an evaluation unit (16) for calibrating the magnetic sensor element (12) based on measurements during which a magnetic excitation field (B1) and/or a magnetic calibration field (B3) and magnetic particles (2) are present in the investigation region.

2. A method for detecting magnetic particles (2) in an investigation region, comprising:
a) generating a magnetic excitation field (B1) in the investigation region with at least one magnetic excitation field generator (11, 13);
b) generating a magnetic calibration field (B3) in the investigation region with at least one magnetic calibration field generator (15), wherein said field has at least temporarily a sufficient magnitude to change the magnetization characteristics of magnetic particles (2) in the investigation region;
c) measuring magnetic reaction fields (B2) with at least one magnetic sensor element (12), wherein said fields are generated by magnetic particles (2) in the investigation region in reaction to the magnetic excitation field (B1) and/or the magnetic calibration field (B3);
d) calibrating the magnetic sensor element (12) based on measurements during which a magnetic excitation field (B1) and/or a magnetic calibration field (B3) and magnetic particles (2) are present in the investigation region.

3. The magnetic sensor device (10) according to claim 1,
characterized in that the amount of magnetic particles (2) in the investigation region is determined based on measurements generated while the magnetic calibration field (B3) vanishes.

4. The magnetic sensor device (10) according to claim 1,
characterized in that the magnetic calibration field (B3) repeatedly vanishes.

5. The magnetic sensor device (10) according to claim 1,
characterized in that the magnetic calibration field (B3) saturates the magnetic particles (2) at least temporarily.

6. The magnetic sensor device (10) according to claim 1,
characterized in that the magnetic excitation field (B1) has an excitation frequency f1 >0.

7. The magnetic sensor device (10) according to claim 1,
characterized in that the magnetic calibration field (B3) has a calibration frequency f3>0.

8. The magnetic sensor device (10) or the method according to claim 7,
characterized in that the excitation frequency f1 has at least approximately the same value as the calibration frequency f3.

9. The magnetic sensor device (10) according to claim 1,
characterized in that the magnetic sensor element (12) is driven with a sensing frequency f2>0.

10. The magnetic sensor device (10) according to claim 1,
characterized in that the magnetic calibration field (B3) in the magnetic sensor element (12) is adjusted to be essentially zero in the sensitive direction of said element.

11. The magnetic sensor device (10) according to claim 1,
characterized in that the component of the measurement signals is determined which is due to the magnetic calibration field (B3) in the magnetic sensor element (12).

12. The magnetic sensor device (10) according to claim 1,
characterized in that the magnetic excitation field generator and/or the magnetic calibration field generator comprises at least one conductor wire (11, 13).

13. The magnetic sensor device (10) according to claim 1,
characterized in that the magnetic excitation field generator and the magnetic calibration field generator are at least partially realized by the same hardware.

14. The magnetic sensor device (10) according to claim 1,
characterized in that the magnetic calibration field generator comprises at least one coil (15).

15. The magnetic sensor device (10) according to claim 1,
characterized in that the sensor unit comprises a Hall sensor or a magneto-resistive element like a GMR (12), a TMR, or an AMR element.

16. Use of the magnetic sensor device (10) according to claim 1 for molecular diagnostics, biological sample analysis, and/or chemical sample analysis, particularly the detection of small molecules.
